(19) United States
(12) Patent Application Publication
(10) Pub. No.: US 2007/0246765 A1
(43) Pub. Date: Oct. 25, 2007

(54) Semiconductor memory device and method for production

(76) Inventor: Lars Bach, Ullersdorf (DE)

Correspondence Address: SLATER & MATSIL LLP, 17950 PRESTON ROAD, SUITE 1000, DALLAS, TX, 75252, US

(21) Appl. No.: 11/394,345

(22) Filed: Mar. 30, 2006

(51) Int. Cl. H01L 29/76

(52) U.S. Cl. 257/314

(57) ABSTRACT

Parallel fins or ridges are arranged on a main surface of a semiconductor substrate. Source/drain regions are provided at top and bottom portions of said fins, and wordlines comprising gate electrodes are arranged in interspaces between neighboring fins. The channels of individual memory cells are directed vertically with respect to the substrate surface.

### TECHNICAL FIELD

The present invention concerns semiconductor memory devices, especially charge-trapping memory devices, and a method of production.

### BACKGROUND

Semiconductor memory devices comprise an array of memory cells, which are arranged on a main surface of a semiconductor substrate. The surface area that is occupied by the memory cell array depends on the lateral dimensions of the individual memory cells, which therefore limit the storage density. There have already been several concepts to reduce the lateral dimensions that are necessary for the memory cells.

If the channel is not planar at the main substrate surface but curved along the walls of a trench, comparatively long channels can be obtained while the distance between the source/drain regions of a single memory cell can be kept small. This corresponds to a folding of the surface plane of the semiconductor body. The gate electrode is arranged in the trench and electrically insulated from the semiconductor material by a layer or layer sequence of dielectric material, which is applied to the sidewalls of the trench. The channel can be confined to only one sidewall of a trench. In this case, there are upper and lower source/drain regions, which are formed at the upper surface of the substrate adjacent to the trench and under the bottom of the trench. The source/drain regions at the bottom are preferably connected by buried bitlines, which are formed by electrically conductively doped regions in the semiconductor material.

A comparable concept, also corresponding to a folding of the surface plane, makes use of semiconductor fins, as they have also been applied in the structure of field effect transistors. The channel region is located in sidewalls of the fins. Source/drain regions are implanted in periodic succession along each fin, and the longitudinal extension of the channel is parallel to the longitudinal extension of the fin. Therefore, the channel length extends within the plane of the main substrate surface. This limits the shrinkability of a memory cell array comprising fins.

### SUMMARY OF THE INVENTION

The semiconductor memory device has a substrate of semiconductor material with a main surface. A plurality of fins of semiconductor material is arranged on the surface parallel at a distance from one another to form interspaces. Lower source/drain regions are located under the fins in the substrate. Upper source/drain regions are located in the fins at a distance from the substrate. Wordlines of electrically conductive material are arranged in the interspaces between the fins. Dielectric material is arranged between the fins and the wordlines. Bitlines electrically connect either a plurality of the lower source/drain regions or a plurality of the upper source/drain regions.

A method for production of memory devices includes providing a substrate having a main surface. A sacrificial layer is applied onto the main surface. The sacrificial layer is structured to form parallel strips that are arranged at a distance from one another. A dopant is implanted to form doped regions comprising lower source/drain regions, using the parallel strips of the sacrificial layer as a mask. A layer of semiconductor material is grown on the surface in areas between the parallel strips to form a plurality of semiconductor fins. The sacrificial layer is removed. A dielectric material is applied on the fins. An electrically conductive material is applied at least into spaces between the fins. The electrically conductive material is structured into wordlines between the fins. An insulation is applied on the wordlines. A dopant that is provided for upper source/drain regions is implanted into upper portions of the fins. An electrically conductive layer contact-connecting the upper source/drain regions is applied. The electrically conductive layer is structured into bitlines running transversely to the wordlines.

These and other aspects, features and advantages of the invention will become apparent from the following brief description of the drawings, detailed description and appended claims and drawings.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 shows a cross-section through an intermediate product of a manufacturing method;

FIG. 2 shows the cross-section according to FIG. 1 for an implantation step;

FIG. 3 shows the plan view onto the intermediate product according to FIG. 2;

FIG. 4 shows the cross-section according to FIG. 2 after the growth of fins;

FIG. 5 shows the cross-section according to FIG. 4 after the application of a lower boundary layer and a charge-trapping layer;

FIG. 6 shows the cross-section according to FIG. 5 after a partial removal of the charge-trapping layer;

FIG. 7 shows the cross-section according to FIG. 6 after the application of an upper boundary layer and an electrically conductive material;

FIG. 8 shows the cross-section according to FIG. 7 after the formation of wordlines;

FIG. 9 shows the cross-section according to FIG. 8 after the application of a dielectric layer;

FIG. 10 shows the cross-section according to FIG. 9 after the formation of wordline insulations and the application of an electrically conductive layer;

FIG. 11 shows the cross-section according to FIG. 10 after the formation of bitlines and the application of an intermetal dielectric and the M0 metal level;

FIG. 12 shows the cross-section according to FIG. 9 after an alternative step of planarization of the dielectric layer;

FIG. 13 shows the cross-section according to FIG. 10 for the embodiment according to FIG. 12;

FIG. 14 shows the cross-section according to FIG. 11 for the embodiment according to FIG. 12;

FIG. 15 shows a 3D section of the product according to FIG. 14;

FIG. 16 shows a cross-section of a layer sequence in the addressing periphery;

FIG. 17 shows the cross-section according to FIG. 16 after the application of electrically conductive layers and a hardmask;

FIG. 18 shows the cross-section according to FIG. 17 after the structuring of conductor stacks and the application of the intermetal dielectric;

FIG. 19 is a plan view of the arrangement of bitlines, wordlines and the electric connections in the M0 metal level;

FIG. 20 shows a cross-section parallel to the wordlines through a semiconductor fin;

FIG. 21 is a cross-section according to FIG. 20, showing the location of the bitline vias;

FIG. 22 is a cross-section according to FIG. 13 of the intermediate product of FIG. 21;

FIG. 23 is a cross-section according to FIG. 21 after the filling of the via holes;

FIG. 24 is a cross-section according to FIG. 22 after the filling of the via holes;

FIG. 25 is a cross-section according to FIG. 23 after the formation of further bitlines; and

FIG. 26 is a cross-section according to FIG. 24 after the formation of further bitlines.

### DETAILED DESCRIPTION OF ILLUSTRATIVE EMBODIMENTS

In one aspect, the semiconductor memory device comprises a substrate of semiconductor material having a main surface, a plurality of fins of semiconductor material being arranged on the substrate surface parallel at a distance from one another to form interspaces, lower source/drain regions located under the fins in the substrate, upper source/drain regions located in the fins at a distance from the substrate, wordlines of electrically conductive material that are arranged in the interspaces between the fins, dielectric material arranged between the fins and the wordlines, and bitlines that electrically connect either a plurality of lower source/drain regions or a plurality of upper source/drain regions.

In a further aspect, the semiconductor memory device comprises a substrate with a main surface, a plurality of parallel semiconductor ridges on the substrate surface, the ridges comprising top and bottom portions, lower source/drain regions located at the bottom portions of the ridges, upper source/drain regions located at the top portions of the ridges, electrically conductive material provided for wordlines between the ridges, dielectric material between the ridges and neighboring wordlines, and bitlines, each bitline connecting a plurality of lower source/drain regions or a plurality of upper source/drain regions.

In still a further aspect, the semiconductor memory device comprises a substrate with a main surface, a fin of semiconductor material arranged on the main surface, source/drain regions formed at a bottom and at a top of the fin, a channel region located in a sidewall of the fin between the source/drain regions, a gate electrode arranged opposite to the sidewall, and a gate dielectric arranged between the sidewall and the gate electrode.

In one aspect, the method for production of memory devices comprises providing a substrate having a main surface, applying a sacrificial layer onto the substrate surface, structuring the sacrificial layer to form parallel strips that are arranged at a distance from one another, implanting a dopant provided for lower source/drain regions by using the parallel strips of the sacrificial layer as a mask, growing a layer of semiconductor material on the surface in areas between the parallel strips to form a plurality of semiconductor fins, removing the sacrificial layer, applying a dielectric material on the fins, applying an electrically conductive material at least into spaces between the fins, structuring the electrically conductive material into wordlines between the fins, applying an insulation on the wordlines, implanting a dopant provided for upper source/drain regions into upper portions of the fins, applying an electrically conductive layer contact-connecting the upper source/drain regions, and structuring the electrically conductive layer into bitlines running transversely to the wordlines.

In a further aspect, the method comprises additionally applying further bitlines running parallel to the wordlines and contact-connecting the lower source/drain regions, which are preferably already connected by buried bitlines formed as doped regions in the substrate.

In still a further aspect, the method for production of memory devices comprises providing a substrate having a main surface, forming parallel ridges of epitaxially grown semiconductor material on the main surface and thereby forming interspaces between neighboring ridges, the ridges comprising sidewalls facing the interspaces, applying a dielectric material at least on the sidewalls of the ridges, forming wordlines of electrically conductive material within the interspaces, and applying an electric insulation on top of the wordlines.

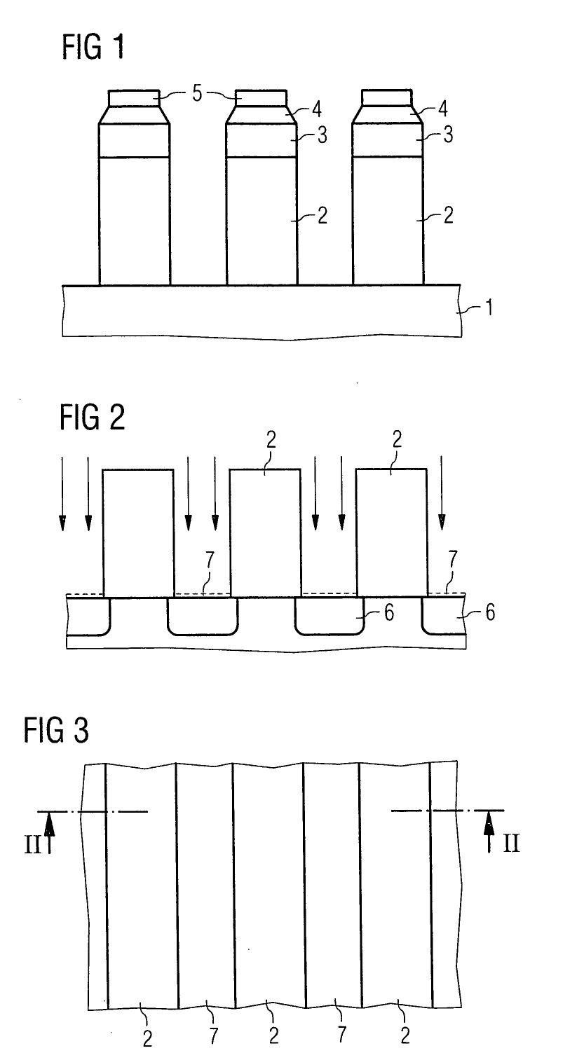

Preferred embodiments of the semiconductor memory device will become apparent from the following description of a preferred production method. FIG. 1 shows a cross-section of an intermediate product. A substrate 1 of semiconductor material is provided with a sacrificial layer 2 on a main surface. The sacrificial layer 2, which can be nitride, is structured into parallel strips by means of a hardmask 3. In the preferred example described here, the hardmask 3 is structured with a supplementary hardmask 4 by a photolithography using a resist 5. The hardmask 3 is preferably a carbon hardmask, and the supplementary hardmask 4 is preferably a nitride hardmask. The nitride can be structured as shown in FIG. 1 with sloping flanks so that the carbon hardmask 3 is structured into strips with smaller distances between them than would be possible with only one hardmask that is structured according to the resist pattern. It is also possible to use a one-layer hardmask only.

The thickness of the sacrificial layer 2 should be larger than the intended channel length of the memory cells to be produced. This dimensional limitation will become clear from the following description. It is preferred to perform the photolithography step with a strictly periodic pattern of equal line widths and space widths. The carbon hardmask enables to reduce the space between the strips of the sacrificial layer 2 typically to values of about 20 nm.

FIG. 2 shows the cross-section according to FIG. 1 after the removal of the resist, the supplementary hardmask 4 and the hardmask 3. A carbon hardmask 3 can be removed by oxidation. Optionally, a thin layer of epitaxially grown semiconductor material, especially silicon, can be provided on the area of the substrate surface between the remaining strips of the sacrificial layer 2. This optional semiconductor layer 7 is indicated with broken lines in FIG. 2. Doping atoms are implanted to form lower source/drain regions 6 in the areas of the substrate surface that are located between the strips of the sacrificial layer 2. This implantation step is indicated with the arrows pointing downwards in FIG. 2.

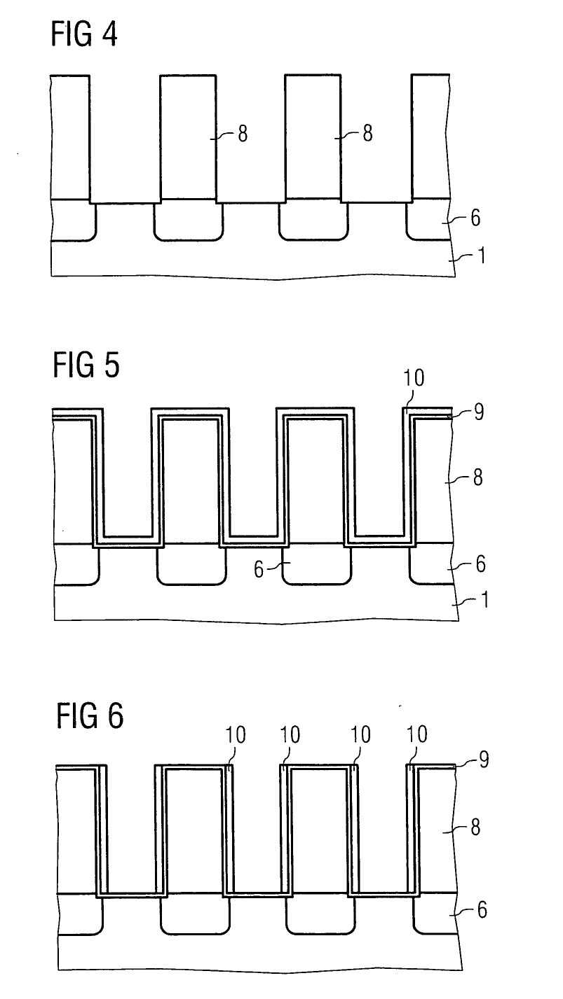

FIG. 3 shows a plan view of the intermediate product according to FIG. 2, showing the strips of the sacrificial layer 2 and the strips of the epitaxially grown semiconductor layer 7. In this embodiment, the width of the strips of the sacrificial layer 2 is larger than the width of the strips of the semiconductor layer 7 because of the application of the carbon hardmask, which renders interspaces that are smaller than the minimal structure obtained by the photolithography. Because of the strip-like pattern of the sacrificial layer, which shields the implant, the doped regions that are produced by the implantation step are also strip-like and form buried bitlines that connect the source/drain regions. Sections of the buried bitlines function as the source/drain regions of the individual memory cells.

FIG. 4 shows a cross-section according to FIG. 2 after the following method steps, in which semiconductor fins 8 are produced by a selective growth of semiconductor material, preferably silicon, on the areas of the substrate surface that had been left free between the strips of the sacrificial layer 2. The sacrificial layer 2 is then removed so that there are free spaces between the semiconductor fins 8, as shown in FIG. 4. The lower source/drain regions 6 are then situated under the semiconductor fins 8 at a respective bottom portion of the fins. Due to the use of the sacrificial layer, the fins 8 are arranged in self-aligned fashion with respect to the lower source/drain regions 6.

If the sacrificial layer 2 is applied from nitride, it can be removed with hot phosphorous acid. If the previous structuring of the sacrificial layer 2 by means of the hardmask rendered a semiconductor surface that is insufficient for the epitaxial growth, especially if the surface is too rough, this can be remedied by the application of a sacrificial oxide, which is subsequently removed by a wet chemical etching to smoothen the surface. Instead, an auxiliary layer, which is applied between the substrate 1 and the sacrificial layer 2 and functions as an etch stop layer when structuring the sacrificial layer, can be used to protect the semiconductor surface. The auxiliary layer is removed before the epitaxial growth.

FIG. 5 shows the cross-section according to FIG. 4 after the application of layers of dielectric materials provided as gate dielectric. The lower boundary layer 9 can be an oxide layer, which can be formed by a dry oxidation with HCl. In this exemplary embodiment, the dielectric materials are selected to form charge-trapping memory cells. To this purpose, a charge-trapping layer 10 is applied of a dielectric material that is suitable for charge trapping, especially nitride if the lower boundary layer 9 is oxide. The nitride charge-trapping layer can be formed, for example, by a conformal deposition of nitride by LPCVD (low-pressure chemical vapor deposition).

FIG. 6 shows the cross-section according to FIG. 5 after a selective nitride etching, which stops on the lower boundary layer 9 and leaves portions of the charge-trapping layer 10 that are limited to the sidewalls of the fins 8. Then an upper boundary layer is applied, which can be oxide.

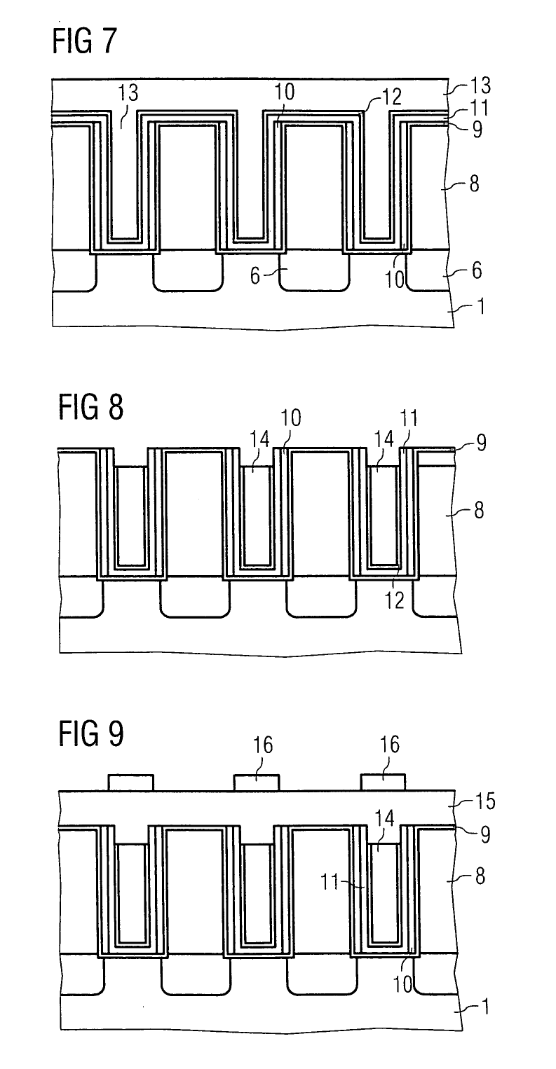

FIG. 7 shows the structure according to FIG. 6 after the application of the upper boundary layer 11. Before an electrically conductive material 13 is deposited, preferably a thin liner 12, which can be Ti/TiN, is conformally deposited. The electrically conductive material 13 can be tungsten. It fills the interspaces between the fins 8 and is provided to form gate electrodes that are connected by wordlines.

FIG. 8 shows the cross-section according to FIG. 7 after the partial removal of the electrically conductive material 13 to form the wordlines 14 within the interspaces between the fins. The electrically conductive material 13 is preferably removed by CMP (chemical mechanical polishing). The CMP step stops when the upper surface of the fins is reached. The material of the upper boundary layer 11, for example oxide, is also removed from the top of the fins so that the upper surface of the fins is laid bare. Then the electrically conductive material is further etched in a subsequent pull-back step in order to form shallow recesses above the wordlines 14. The recesses will later serve to ensure sufficient electric insulation to the upper bitlines.

FIG. 9 shows the cross-section according to FIG. 8 after the application of a dielectric layer 15 and a further mask 16. The dielectric layer 15 can be formed of TEOS (Tetraethylorthosilicate). The mask 16 can be a resist mask and is used to structure the dielectric layer 15 so that wordline insulations are formed on top of the wordlines 14.

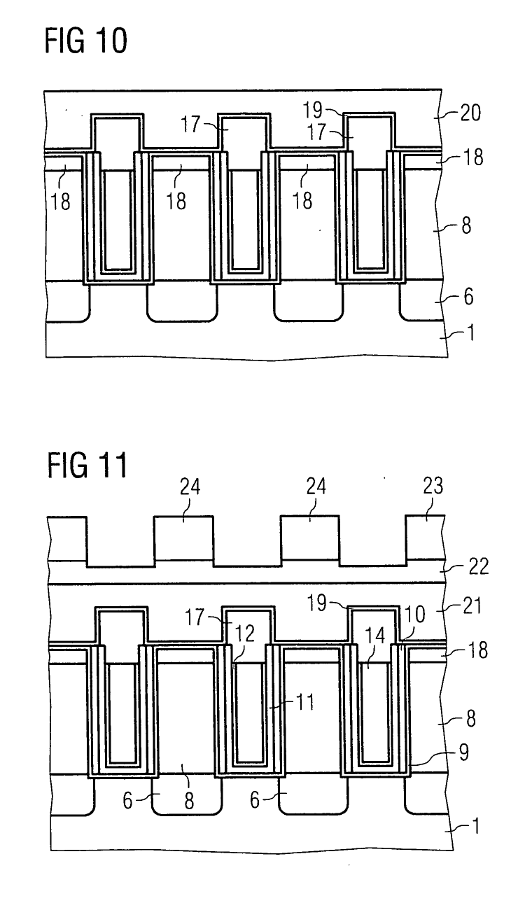

FIG. 10 shows the cross-section according to FIG. 9 after the formation of the wordline insulations 17, separate for each wordline. Upper source/drain regions 18 are formed by a further implantation of doping atoms, by which doped regions are formed in top portions of the fins. Then, a thin liner 19, which can be Ti/TiN, is preferably applied, before an electrically conductive layer 20 is deposited, which may be tungsten and which is provided for bitlines. The electrically conductive layer 20 contact-connects the upper source/drain regions 18. The electrically conductive layer 20 is structured into separate bitlines running transversely to the wordlines 14 and contact-connecting rows of upper source/drain regions 18. The bitlines can be structured by means of a further hardmask, which can be formed of TEOS, for example. A wet reactive ion etching is preferably performed to remove the electrically conductive material in areas that are left free by the further hardmask.

FIG. 11 shows the structure after the formation of the bitlines 21, the application of an intermetal dielectric 22, and the formation of a structured M0 metal level 23 optionally comprising further bitlines 24. The further bitlines 24 are parallel to the buried bitlines and can be provided additionally to compensate for a larger track resistance of the buried bitlines. The intermetal dielectric 22 can be BPSG (boron phosphorus silicate glass), and the M0 metal level 23 can be AlCu according to standard semiconductor technology. A plan view onto the product according to FIG. 11 looks similar to the plan view of FIG. 3, not drawn to scale, if the strips of the semiconductor layer 7 are interchanged with the further bitlines 24 and the strips of the sacrificial layer 2 are interchanged with the free areas of the intermetal dielectric 22 between the further bitlines 24.

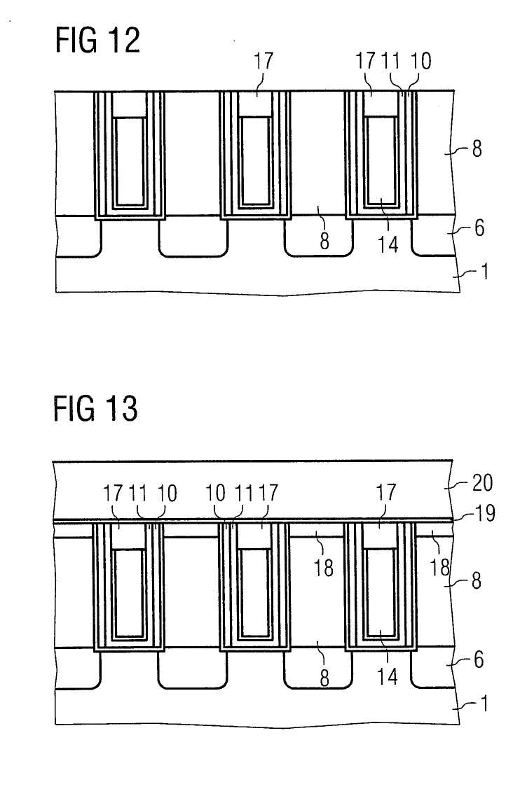

FIG. 12 shows a cross-section according to FIG. 9 after the application of the dielectric layer 15 for an alternative embodiment. In this alternative embodiment, the dielectric layer 15 is not structured by the mask 16, but instead planarized down to the upper surface of the semiconductor fin 8. This planarization step can be performed by chemical mechanical polishing. Because of the recessed wordlines 14, the residual material of the dielectric layer 15 is sufficient to form the wordline insulation 17 shown in FIG. 12. On the other hand, this embodiment has the advantage of a planar surface, which is especially favorable with respect to the integrated circuits of the addressing periphery.

FIG. 13 shows the cross-section corresponding to FIG. 10 for the alternative embodiment shown in FIG. 12. Corresponding elements are designated with the same reference numerals so that they need not be described again. The conductor 20 have a constant cross-section along their longitudinal extensions.

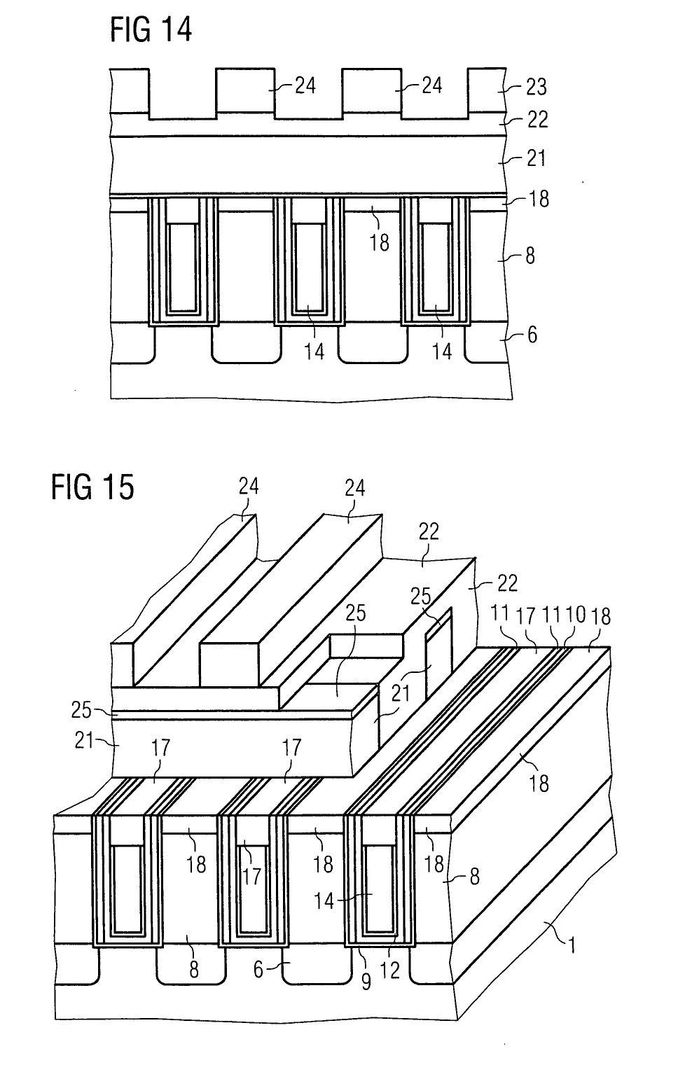

FIG. 14 shows the cross-section corresponding to FIG. 11 for the alternative embodiment, which can be provided with the further bitlines 24 in a similar way.

FIG. 15 shows a three-dimensional section of the product according to the cross-section of FIG. 14. The preferred arrangement of the strip-like doped regions that comprise the lower source/drain regions 6, the bitlines 21, the further bitlines 24 transverse to the bitlines 21, and the wordlines 14, and the arrangement of the lower source/drain regions 6, the upper source/drain regions 18, and the vertical channels in the sidewalls of the semiconductor fins 8 of this semiconductor memory device are clearly displayed in FIG. 15. The further bitlines 24 run parallel to the buried bitlines formed by the strip-like doped regions that comprise the lower source/drain regions 6. The further bitlines 24 are preferably connected to the buried bitlines at periodic intervals between groups of the first bitlines 21. The further bitlines 24 render a considerably lower track resistance than the track resistance of the buried bitlines alone. The channel length can be adapted by the height of the fins and the depth of the lower junctions of the upper source/drain regions. The wordlines 14 run along the fins 8 and comprise the gate electrodes of the individual memory cells. This structure is especially appropriate for the formation of charge-trapping memory cells. The vertical arrangement of the channels enables to manufacture memory cells occupying a surface area of 2F².

FIG. 15 shows an additional upper bitline insulation 25, which can be formed by a residual layer of a hardmask that is used to structure the bitlines 21 and also conductor tracks in the addressing periphery.

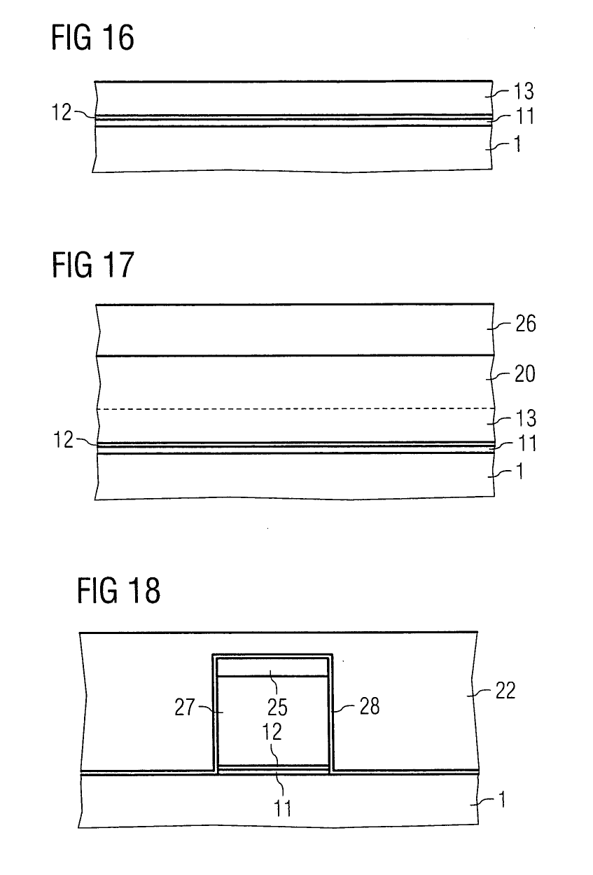

The integration of the memory cell array with the logic circuitry of an addressing periphery will become clear from the following description in conjunction with FIGS. 16 to 18. FIG. 16 shows a cross-section in the area of the addressing periphery. In this area, the upper boundary layer 11, the liner 12, and the electrically conductive material 13 are applied on the substrate 1 as a sequence of planar layers.

FIG. 17 shows the cross-section according to FIG. 16 after the next process steps. After the dielectric layer 15 has been deposited and the planarization or structuring of the dielectric layer 15 has been effected to form the wordline insulation 17, the memory cell array is covered, preferably with a resist layer, and the dielectric layer 15 is removed from the area of the addressing periphery. If the dielectric layer 15 is oxide, for instance, an oxide deglaze is performed in the peripheral areas. After the application of the electrically conductive layer 20, a hardmask 26 is formed, which can be nitride. FIG. 17 shows the boundary between the electrically conductive material 13 and the electrically conductive layer 20 with a broken line to indicate that both materials can be the same metal, preferably tungsten. The hardmask 26 is used to form the bitlines 21 and conductor stacks of the addressing periphery.

FIG. 18 shows the structure in the addressing periphery after the structuring of the conductor stacks 27. Residual layer portions of the hardmask 26 can remain as upper insulation 25 on the conductor stacks 27 and, as already shown in FIG. 15, on the bitlines 21. A further liner 28 is preferably applied, which can be SiON, for example. Then the intermetal dielectric 22 is applied, which can be boron phosphorus silicate glass. FIG. 18 shows the cross-section after the planarization of the intermetal dielectric 22, for example by chemical mechanical polishing. Since the intermetal dielectric 22 is planarized simultaneously in the areas of the memory cell array and the addressing periphery, a completely planar surface is obtained so that the first metal level M0 can be applied on a smooth surface without any steps.

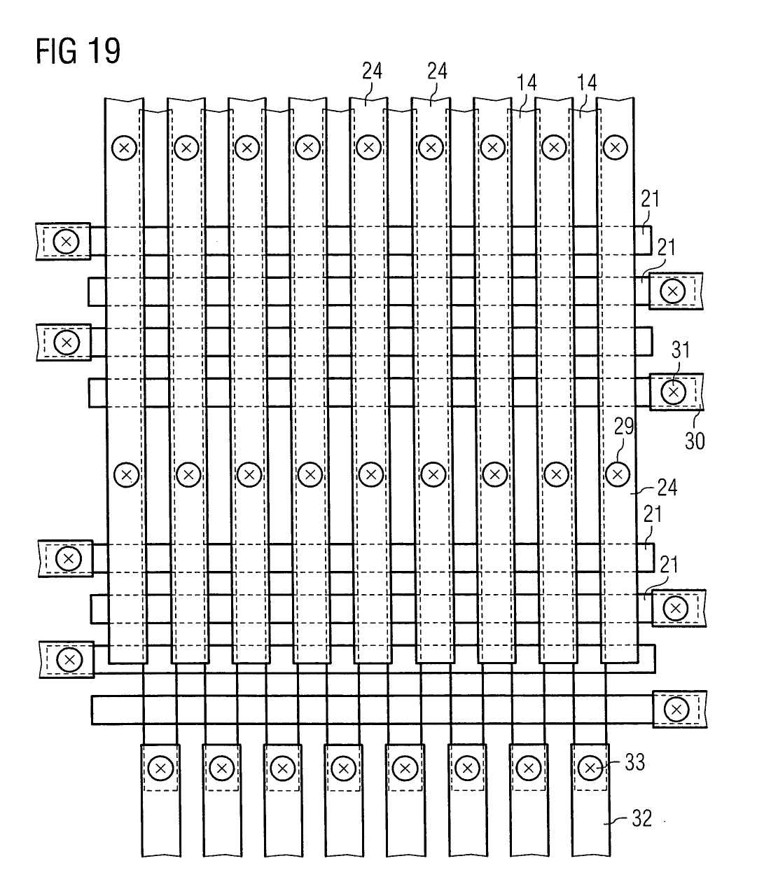

FIG. 19 shows a plan view onto the arrangement of wordlines and bitlines. The upper level is the M0 metal level; the levels below are indicated as concealed contours by broken lines. The further bitlines 24 are uppermost and are structured within the first metal level M0. There are bitline vias 29 at intervals along the further bitlines 24. These bitline vias 29 electrically connect the further bitlines 24 to the doped regions forming the buried bitlines, which connect the lower source/drain regions 6. In this manner, the further bitlines 24 reinforce the buried bitlines to reduce the track resistance considerably. The sequence of bitlines 21, which run transversely to the wordlines 14 and the further bitlines 24, is interrupted at intervals by larger interspaces, in which the bitline vias 29 are arranged. The drawing is not to scale; the lateral dimensions of the wordlines and bitlines and their distances from one another can be adapted to the relevant embodiment. The plan view of FIG. 19 further shows bitline connections 30 and wordline connections 32, which are formed in the first metal level M0. The bitline connections 30 are connected to the bitlines 21 by bitline contacts 31; and the wordline connections 32 are connected to the wordlines by wordline contacts 33. The shape of the contacts can vary, and they are indicated in FIG. 19 schematically by circles and crosses.

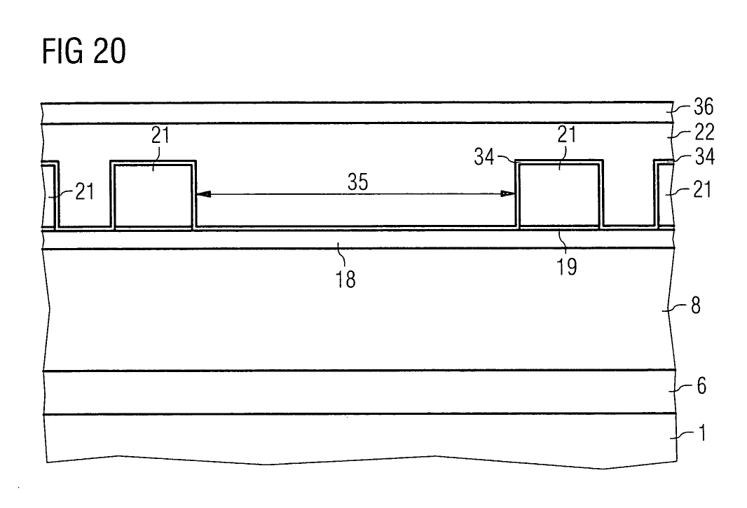

A preferred fabrication method of the bitline vias 29 will now be described in conjunction with FIGS. 20 to 26. FIG. 20 shows a cross-section through one of the semiconductor fins 8 parallel to the wordlines. Under the semiconductor fin 8, the substrate 1 is provided with lower source/drain regions 6. The upper source/drain regions 18 are contact-connected with the bitlines 21, where the intermediate liner 19 can be provided as described above. The bitlines 21 are preferably applied in a strictly periodic pattern. In the locations in which the further bitlines are to be connected with the doped regions of the lower source/drain regions 6, the bitlines 21 are removed selectively to the semiconductor material. This process step can be performed by the application of a hardmask formed of oxide or nitride, which is structured by photolithography. The electrically conductive material of the bitlines 21 can be removed by RIE (reactive ion etching), for example, if the material of the bitlines 21 is tungsten or another metal. The bitlines 21 are removed in such a manner that interspaces 35 are formed, in which the bitline vias can be arranged. The interspaces 35 can each comprise the area that had been occupied by one bitline or by a certain small number of bitlines. Then a liner 34 is preferably applied, which also covers the surface areas between the bitlines. The liner is preferably nitride. Then the bitlines 21 are encapsulated with the intermetal dielectric 22, which can be BPSG (boron phosphorus silicate glass). The upper surface of the intermetal dielectric 22 is produced sufficiently planar so that a hardmask 36, preferably of nitride, can be applied and structured. If necessary, a carbon hardmask can additionally be used to adjust the lithography conditions.

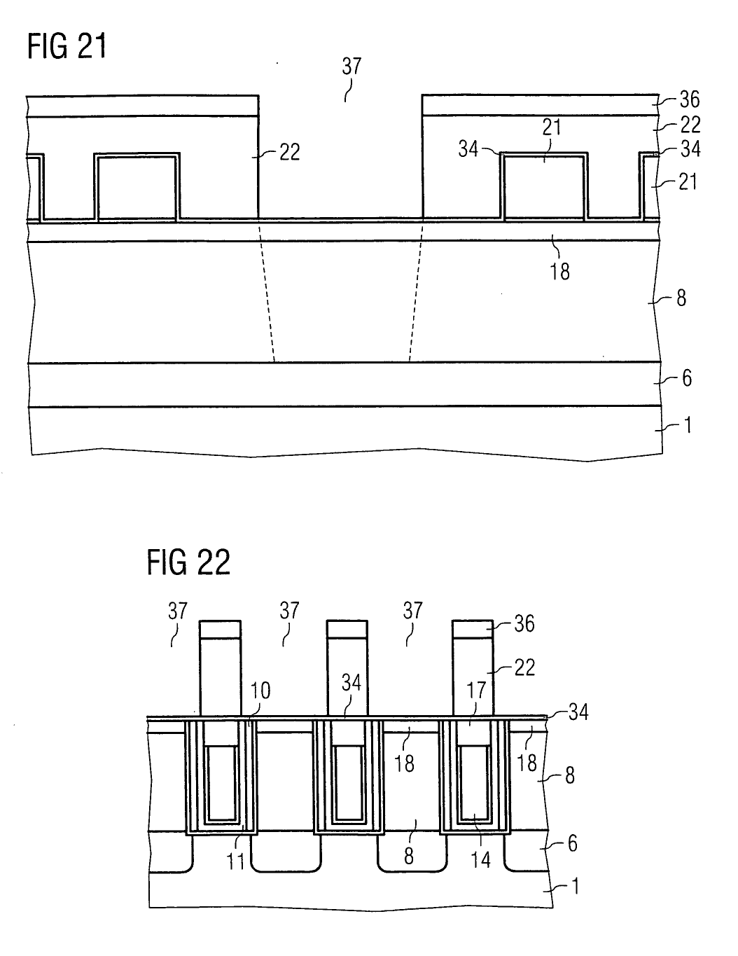

FIG. 21 shows the cross-section according to FIG. 20 after the structuring of the hardmask 36 to form openings 37 in the areas of the bitline vias that are to be produced. Using the hardmask, the openings 37 are formed in the intermetal dielectric 22. If a liner 34 has been applied, an etching step to remove the intermetal dielectric 22 in the regions of the openings 37 stops on the liner 34, which thus protects the wordline insulation 17. Then the semiconductor material of the semiconductor fins 8 is selectively removed in the region that is indicated by broken lines in FIG. 21. In this step the encapsulation of the wordlines is not attacked.

FIG. 22 shows a cross-section according to FIG. 13 transversely to the wordlines 14. This cross-section shows that the openings 37 are formed between the areas that are occupied by the wordlines 14. The removal of the semiconductor material of the semiconductor fins 8 is self-aligned to the dielectric material of the layers 9, 10, 11 that are present on the sidewalls between the fins and the wordlines.

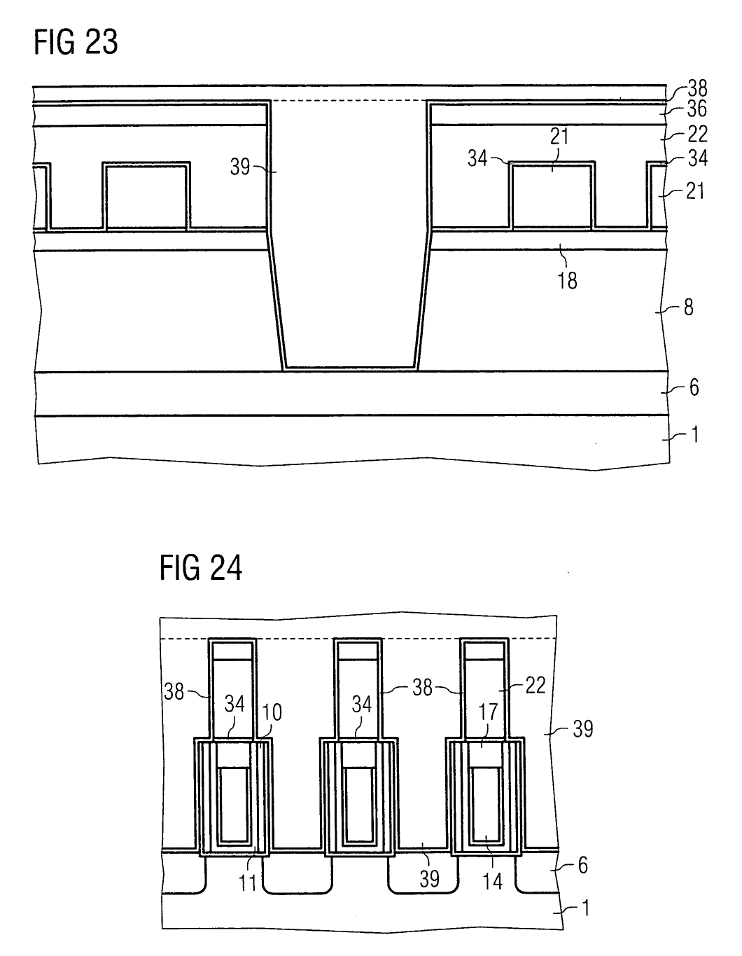

FIG. 23 shows a cross-section according to FIG. 21 after the formation of the via holes and the application of a filling comprising an electrically conductive material. If the filling 39 is tungsten, for instance, it is preferred to apply a thin liner 38 comprising Ti/TiN first. The filling 39 is planarized to the level shown by the horizontal broken line in FIG. 23.

FIG. 24 shows the corresponding cross-section according to the cross-section of FIG. 22 for the intermediate product after the application of the filling 39.

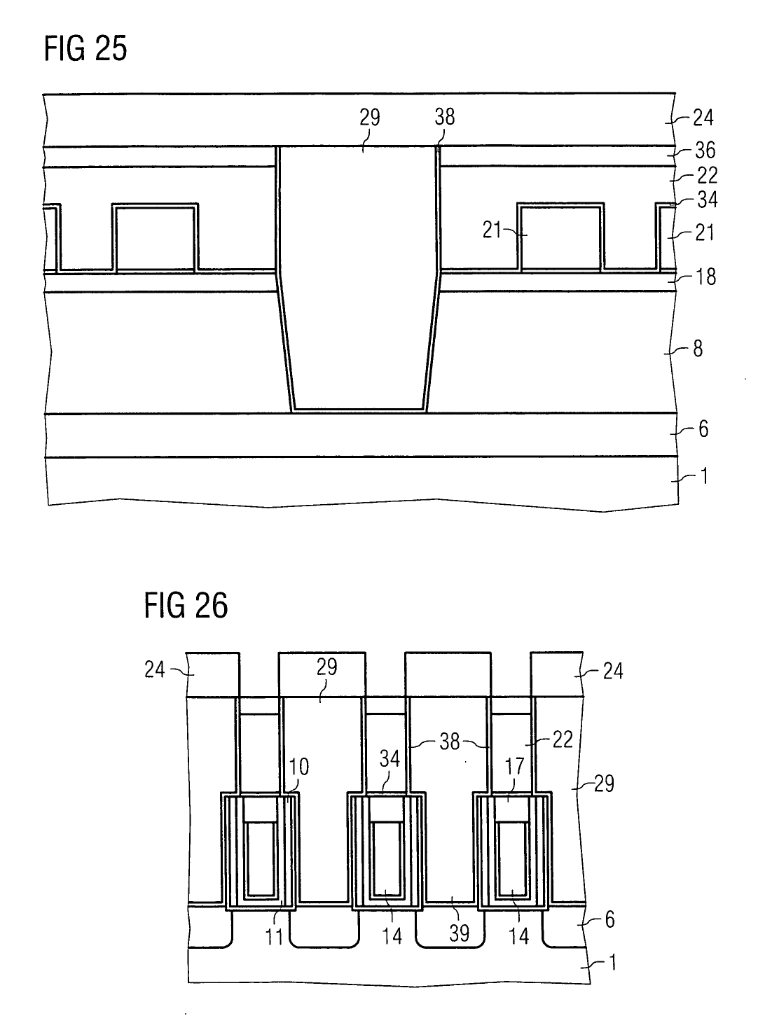

FIG. 25 shows the cross-section according to FIG. 23 after the planarization of the filling to form the bitline vias 29 and the formation of the further bitlines 24, which connect the bitline vias 29 from above.

FIG. 26 shows the cross-section according to FIG. 24 after the formation of the upper bitlines 24, which are preferably structured to be self-aligned with the bitline vias 29, which are present in the positions that are shown in an exemplary embodiment in FIG. 19.

Although the present invention and its advantages have been described in detail, it should be understood that various changes, substitutions and alterations can be made herein without departing from the spirit and scope of the invention as defined by the appended claims.

What is claimed is:

1. A semiconductor memory device, comprising:
a semiconductor substrate having a main surface;
a plurality of fins of semiconductor material disposed on said main surface, said fins arranged parallel at a distance from one another to form interspaces;
lower source/drain regions located under said fins in said semiconductor substrate;
upper source/drain regions located in said fins at a distance from said semiconductor substrate;
wordlines of electrically conductive material that are arranged in the interspaces between said fins;
dielectric material arranged between said fins and said wordlines; and
a plurality of bitlines, each bitline electrically connecting either a plurality of said lower source/drain regions or a plurality of said upper source/drain regions.

2. The semiconductor memory device according to claim 1, wherein said dielectric material comprises at least one layer of a material that is suitable for charge-trapping.

3. The semiconductor memory device according to claim 1, wherein bitlines that couple a plurality of upper source/drain regions run transversely to said wordlines.

4. The semiconductor memory device according to claim 3, wherein bitlines that connect a plurality of lower source/drain regions run parallel to said wordlines.

5. The semiconductor memory device according to claim 1, wherein each fin has sidewalls and wherein channel regions are provided in said sidewalls.

6. The semiconductor memory device according to claim 5, wherein said channel regions have a longitudinal extension in a vertical direction with respect to said main surface.

7. A semiconductor memory device, comprising:
a substrate with a main surface;
a plurality of parallel semiconductor ridges on said main surface;
said ridges comprising top and bottom portions;
lower source/drain regions located at said bottom portions;
upper source/drain regions located at said top portions;
electrically conductive material between said ridges, said material being provided for wordlines;
dielectric material between said ridges and neighboring wordlines; and
a plurality of bitlines, each bitline electrically connecting one of a plurality of lower source/drain regions or a plurality of upper source/drain regions.

8. The semiconductor memory device according to claim 7, wherein said dielectric material comprises at least one layer of a material that is suitable for charge-trapping.

9. The semiconductor memory device according to claim 7, wherein bitlines that couple a plurality of upper source/drain regions run transversely to said wordlines.

10. The semiconductor memory device according to claim 7, wherein each ridge includes sidewalls between said top and bottom portions and wherein channel regions are provided in said sidewalls.

11. The semiconductor memory device according to claim 10, wherein said channel regions have a longitudinal extension in a vertical direction with respect to said main surface.

12. A semiconductor memory device, comprising:
a substrate with a main surface;
a fin of semiconductor material being arranged on said main surface, said fin having a top, a bottom and a sidewall;
source/drain regions being formed at said bottom and at said top of said fin;
a channel region located in said sidewall between said source/drain regions;
a gate electrode arranged adjacent said sidewall; and
a gate dielectric arranged between said sidewall and said gate electrode.

13. The semiconductor memory device according to claim 12, wherein said gate dielectric comprises at least one dielectric material that is suitable for charge-trapping.

14. A method for forming a memory device, the method comprising:
providing a semiconductor substrate having a main surface;
forming a sacrificial layer over said main surface;
structuring said sacrificial layer to form parallel strips that are arranged at a distance from one another;
implanting a dopant to form doped regions comprising lower source/drain regions, using said parallel strips of said sacrificial layer as a mask;
growing a layer of semiconductor material on said main surface in areas between said parallel strips to form a plurality of semiconductor fins;
removing said sacrificial layer;
forming a dielectric material over said fins;
forming an electrically conductive material at least into spaces between said fins;
structuring said electrically conductive material into wordlines between said fins;
forming an insulation on said wordlines;
implanting a dopant provided for upper source/drain regions into upper portions of said fins;
forming an electrically conductive layer contact-connecting said upper source/drain regions; and
structuring said electrically conductive layer into bitlines running transversely to said wordlines.

15. The method according to claim 14, further comprising applying further bitlines running parallel to said wordlines and contact-connecting said doped regions comprising said doped regions comprising said lower source/drain regions.

16. The method according to claim 15, further comprising forming bitline vias provided to connect said further bitlines and said doped regions comprising said lower source/drain regions.

17. The method according to claim 16, further comprising:
before forming the further bitlines, removing bitlines that run transversely to the wordlines in locations that are provided for said bitline vias;
applying an intermetal dielectric;
forming a hardmask;
forming openings in said hardmask in positions that are provided for said bitline vias;
using said hardmask to form openings in said intermetal dielectric and said semiconductor fins, thereby uncovering upper surfaces of said doped regions comprising said lower source/drain regions;
applying a filling of said openings with electrically conductive material to form said bitline vias; and
forming said further bitlines to contact said bitline vias.

18. The method according to claim 17, further comprising applying said filling from tungsten.

19. The method according to claim 14, wherein applying a dielectric material over the fins comprises applying said dielectric material over said fins as a layer sequence comprising at least one dielectric material suitable for charge-trapping.

20. The method according to claim 19, wherein said fins have sidewalls, and wherein said layer sequence comprising at least one dielectric material suitable for charge-trapping is formed on said sidewalls.

21. The method according to claim 19, wherein applying a dielectric material over the fins comprises applying said layer sequence as an oxide-nitride-oxide layer sequence.

22. The method according to claim 14, wherein forming an electrically conductive material comprises depositing tungsten.

23. The method according to claim 14, wherein applying further bitlines comprises applying further bitlines being formed of tungsten.

24. A method for producing memory devices, the method comprising:
providing a semiconductor substrate having a main surface;
forming parallel ridges of epitaxially grown semiconductor material on said main surface and interspaces between neighboring ridges, said ridges comprising sidewalls facing said interspaces;
applying a dielectric material at least on said sidewalls of said ridges;
forming wordlines of electrically conductive material within said interspaces; and
applying an electric insulation over said wordlines.

25. The method according to claim 24, wherein applying said dielectric material comprises applying a memory layer provided for charge-trapping.

26. The method according to claim 24, further comprising forming upper and lower source/drain regions at top and bottom portions of said ridges.

27. The method according to claim 26, further comprising forming bitlines that electrically connect pluralities of said upper source/drain regions and run transversely to said wordlines.

28. The method according to claim 27, further comprising forming further bitlines that electrically connect pluralities of said lower source/drain regions and run parallel to said wordlines.

29. The method according to claim 28, further comprising forming bitline vias provided to connect said further bitlines and said lower source/drain regions.

30. The method according to claim 29, further comprising:
removing bitlines that run transversely to the wordlines before forming the further bitlines in locations that are provided for said bitline vias;
applying a liner on the bitlines and between the bitlines;
applying an intermetal dielectric;
forming a hardmask;
forming openings in said hardmask in positions that are provided for said bitline vias;
using said hardmask to form openings in said intermetal dielectric and said semiconductor fins;
applying a filling of said openings with electrically conductive material to form said bitline vias; and
forming said further bitlines to contact said bitline vias.

31. The method according to claim 30, wherein applying a filling comprises applying said filling from tungsten.
